(19) United States
(12) Patent Application Publication
(10) Pub. No.: US 2012/0074562 A1
(43) Pub. Date: Mar. 29, 2012

(54) Three-Dimensional Integrated Circuit Structure with Low-K Materials

(75) Inventors: Chen-Hua Yu, Hsin-Chu (TW); Wen-Chih Chiou, Miaoli (TW); Tsang-Jiuh Wu, Hsin-Chu (TW)

(73) Assignee: Taiwan Semiconductor Manufacturing Company, Ltd., Hsin-Chu (TW)

(21) Appl. No.: 12/890,094

(22) Filed: Sep. 24, 2010

(51) Int. Cl. H01L 23/485; H01L 21/762

(52) U.S. Cl. 257/737; 438/107; 257/E23.021; 257/E21.545

(57) ABSTRACT

A device includes an interposer free from active devices therein. The interposer includes a substrate; a through-substrate via (TSV) penetrating through the substrate; and a low-k dielectric layer over the substrate.

### BACKGROUND

To increase the density of package structures, multiple device dies may need to be packaged in a same package structure. To accommodate multiple device dies, an interposer is typically used to bond device dies thereon, with through-substrate vias (TSVs) formed in the interposer.

It was found that since low-k dielectric materials are commonly used in the device dies, low-k delamination and cracking may occur in the devices dies. However, this problem cannot be solved by not using low-k materials. If the low-k dielectric layers are removed from the device dies, RC delay will be increased since the low-k dielectric materials have the effect of reducing RC delay. Further, the bonding between device dies and interposers may be performed through metal bumps. When the device dies are bonded to interposers, the metal bumps also suffer from cracking.

### BRIEF DESCRIPTION OF THE DRAWINGS

For a more complete understanding of the embodiments, and the advantages thereof, reference is now made to the following descriptions taken in conjunction with the accompanying drawings, in which:

FIG. 1 illustrates a cross-sectional view of a three-dimensional integrated circuit (3DIC) structure, wherein an interposer is bonded to a die; and

FIG. 2 illustrates a top view of redistribution lines in an interposer.

### DETAILED DESCRIPTION OF ILLUSTRATIVE EMBODIMENTS

The making and using of the embodiments of the disclosure are discussed in detail below. It should be appreciated, however, that the embodiments provide many applicable inventive concepts that can be embodied in a wide variety of specific contexts. The specific embodiments discussed are merely illustrative, and do not limit the scope of the disclosure.

A novel three-dimensional integrated circuit (3DIC) structure is provided in accordance with an embodiment. The variations of the embodiment are discussed. Throughout the various views and illustrative embodiments, like reference numbers are used to designate like elements.

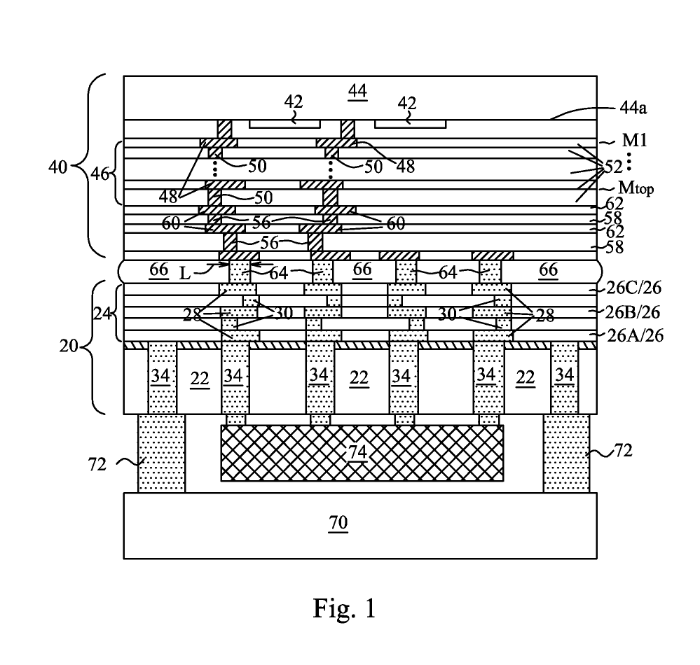

FIG. 1 illustrates a cross-sectional view of a 3DIC structure in accordance with an embodiment. Interposer 20, which includes substrate 22 and interconnect structure 24, is formed. Substrate 22 may be formed of a semiconductor material such as silicon. Alternatively, substrate 22 is formed of a dielectric material. Interposer 20 is substantially free from integrated circuit devices, including active devices such as transistors. Furthermore, interposer 20 may include, or may be free from, passive devices such as capacitors, resistors, inductors, varactors, and/or the like.

Interconnect structure 24 is formed over substrate 22. Interconnect structure 24 includes one or more dielectric layers 26, which include dielectric layers 26A, 26B, and 26C. The dielectric layers 26A and 26B represent inter-layered dielectric (ILD) layers, and the dielectric layer 26C represents a top dielectric layer. In some embodiments, the top dielectric layer is in contact with underfill 66. Metal lines 28 and vias 30 are formed in dielectric layer(s) 26. Throughout the description, the side of interposer 20 including interconnect structure 24 is referred to as a front side, and the opposite side is referred to as a backside. Metal lines 28 and vias 30 are referred to as redistribution lines (RDLs). Further, through-substrate vias (TSVs) 34 are formed in substrate 22, and are electrically coupled to RDLs 28/30. Although not shown, a backside interconnect structure, which may comprise redistribution lines formed in dielectric layers, may also be formed, wherein the backside interconnect structure and interconnect structure 24 are on opposite sides of substrate 22.

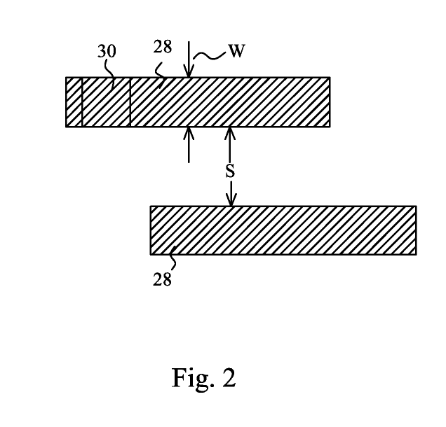

FIG. 2 illustrates a top view of exemplary RDLs 28/30. In an embodiment, the critical dimension W of RDLs 28/30 is greater than about 0.3 μm. The spacing S between neighboring RDLs 28/30 throughout interposer 20 may be greater than about 0.3 μm. Due to the great values of dimension W and spacing S, the RC delay caused by the parasitic capacitance between RDLs 28/30 is small, and may be ignored.

One or more of dielectric layers 26 comprises a low-k dielectric material. The k value of the low-k dielectric material may be lower than 3.8, lower than 3.5, or even lower than 3.0. In an embodiment, a lower dielectric layer 26, such as dielectric layer 26A, is a low-k dielectric layer, while one or more upper dielectric layer 26, such as dielectric layer 26B and/or 26C, is a non-low-k dielectric layer, with the k value of non-low-k dielectric layer being greater than 3.8, and possibly greater than 4.0. In alternative embodiments, all of dielectric layers 26 in interconnect structure 24 including top dielectric layer 26C and all underlying dielectric layers 26 are low-k dielectric layers. The materials of low-k dielectric layers 26 include, but are not limited to, polyimide, fluorine-doped oxides, polymers, chemicals that may be expressed as SiOₓC_{y}H_{z}, and combinations thereof. The materials of the non-low-k dielectric layer(s), if any, in dielectric layers 26 may be formed of un-doped silicate glass (USG), silicon oxide, silicon nitride, polyimide, and the like. It is noted that depending on specific materials, polyimide may be a low-k dielectric material with a k value as low as 3.0, or a non-low-k dielectric material with a k value as high as 4.0. If the backside interconnect structure (not shown) is formed, the backside interconnect structure may be free from any low-k dielectric layer, or may include low-k dielectric layer(s).

Die 40 may be a device die including active devices 42, which may include transistors, for example. Further, die 40 may be a high-performance die including logic circuits. Substrate 44 in die 40 may be a semiconductor substrate, such as a bulk silicon substrate, although it may include other semiconductor materials such as group III, group IV, and/or group V elements. Integrated circuit devices 42 may be formed at the front surface 44a of substrate 44. Interconnect structure 46, which includes metal lines 48 and vias 50 formed in dielectric layer 52, is formed on the front side of substrate 44, with metal lines 48 and vias 50 being electrically coupled to integrated circuit devices 42. Metal lines 48 and vias 50 may be formed of copper or copper alloys, and may be formed using damascene processes.

Dielectric layers 52 may comprise one or more low-k dielectric layer with k values lower than 3.8, lower than about 3.0, or lower than about 2.5. The dielectric layers 52 in metallization layers denoted as M1 through Mtop may be low-k dielectric layers. Further, die 40 may include additional metal layers formed of low-k dielectric layers. In an exemplary embodiment, the top-metal vias 56 are formed in low-k dielectric layers 58, which may be formed of polyimide, for example. On the other hand, redistribution lines 60 may be formed in non-low-k dielectric layers 62. The non-low-k dielectric layer 62 has a k value greater than that of the low-k dielectric layer 26. For example, the non-low-k dielectric layer 62 a k value greater than 3.8.

The k value (referred to as a first low-k value hereinafter) of the low-k dielectric layers 26 in interposer 20 may be substantially equal to the k value (referred to as a second low-k value hereinafter) of the low-k dielectric layers 52 (and possibly 58) in die 40, and the lower the second low-k value is, the lower the first low-k value is used. In an exemplary embodiment, a difference between the first low-k value and the second low-k value is smaller than about 1.5. In some embodiments, the difference between the first low-k value and the second low-k value is smaller than about 0.5, or lower than about 0.3.

Metal bumps 64 are formed to bond die 40 to interposer 20. In an embodiment, metal bumps 64 are copper bumps. In alternative embodiments, metal bumps 64 are solder bumps. The lateral size L of metal bumps 64 may be less than about 50 μm, and hence metal bumps 64 may also be referred to as micro-bumps (u-bumps). Underfill 66 is disposed into the gap between die 40 and interposer 20.

Interposer 20 may also be bonded to package substrate 70 through bumps 72, which may also be copper bumps or solder bumps. Die 40 may be electrically coupled to package substrate 70 through TSVs 34. In an embodiment, secondary die 74 is bonded to interposer 20. Secondary die 74 may be a memory die, for example, although it may also be a high-performance die comprising logic circuits such as a central processing unit (CPU) die. Secondary die 74 and die 40 are on opposite sides of interposer 20, and may be electrically coupled to each other through TSVs 34. In the embodiments wherein secondary die 74 comprises a low-k dielectric layer(s) (not shown), interposer 20 may also include a low-k dielectric layer (not shown) between substrate 22 and secondary die 74. In alternative embodiments, no secondary die is bonded to interposer 20.

It is observed that since low-k dielectric materials exist in both interposer 20 and die 40, the low-k dielectric materials on opposite ends (with one end facing die 40, and the other end facing interposer 20) have well-matched thermal and mechanical characteristics such as coefficient of thermal expansion (CTE). Accordingly, during thermal cycles performed to the 3DIC structure as shown in FIG. 1, the stress applied to metal bumps 64 is reduced, resulting in a smaller chance of cracking in metal bumps 64. It is further observed that since the critical dimensions and spacings in the RDLs in interposer 20 have high values, the RC delay caused by parasitic capacitance of the RDLs is small, and hence the introduction of the low-k dielectric materials into interposer 20 may have little, if any, effect to the improvement in RC delay.

In accordance with embodiments, a device includes an interposer free from active devices therein. The interposer includes a substrate; a TSV penetrating through the substrate; and a low-k dielectric layer over the substrate.

In accordance with alternative embodiments, a device includes an interposer free from active devices therein, wherein the interposer includes a substrate; a TSV penetrating through the substrate; and a low-k dielectric layer over the substrate. The device further includes a die including active devices therein; a metal bump bonding the interposer to the die with the low-k dielectric layer being between the metal bump and the substrate of the interposer; and an underfill disposed between the die and the interposer.

In accordance with yet other embodiments, a device includes an interposer free from transistors therein, wherein the interposer includes a silicon substrate; a TSV penetrating through the silicon substrate; and a low-k dielectric layer on a first side of the silicon substrate. The interposer is free from any low-k dielectric layer on a second side of the silicon substrate opposite the first side.

Although the embodiments and their advantages have been described in detail, it should be understood that various changes, substitutions and alterations can be made herein without departing from the spirit and scope of the embodiments as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A device comprising:
an interposer free from active devices therein, wherein the interposer comprises:
a substrate;
a through-substrate via (TSV) penetrating through the substrate; and
a first dielectric layer over the substrate, wherein the first dielectric layer has a first k value lower than about 3.8.

2. The device of claim 1, wherein the first k value is lower than about 3.5.

3. The device of claim 1, wherein the first k value is lower than about 3.0.

4. The device of claim 1, wherein the substrate is a semiconductor substrate comprising silicon.

5. The device of claim 1, wherein the substrate is a dielectric substrate.

6. The device of claim 1, wherein the interposer comprises a plurality of second dielectric layers over the substrate, and a redistribution line formed in the plurality of second dielectric layers, and wherein at least one of the plurality of second dielectric layers has a second k value lower than about 3.8.

7. The device of claim 6, wherein critical dimension of the redistribution line is greater than about 0.3 μm.

8. The device of claim 1 further comprising:
a first die; and
a metal bump bonding the first die to a first side of the interposer, wherein the first dielectric layer is between the substrate and the die.

9. The device of claim 8, wherein the first dielectric layer is a top dielectric layer of the interposer.

10. The device of claim 8, wherein the interposer comprises a top dielectric layer formed over the first dielectric layer and having a k value greater than the first k value of the first dielectric layer.

11. The device of claim 8 further comprising an underfill material disposed between the first die and the interposer, wherein the first dielectric layer contacts the underfill material.

12. The device of claim 8 further comprising a package substrate bonded to a second side of the interposer, opposite to the first side of the interposer.

13. The device of claim 8, wherein the first die comprises a third dielectric layer with a third k value lower than about 3.8.

14. The device of claim 13, wherein a difference between the first k value of the first dielectric layer and the third k value of the third dielectric layer is smaller than about 1.5.

15. The device of claim 8, further comprising a second die bonded to a second side of the interposer, opposite to the first side of the interposer.

16. A method of forming a device, comprising:
providing an interposer substrate having a first side and a second side opposite to the first side;
forming a through-substrate via (TSV) passing through the interposer substrate;
forming a plurality of inter-layered dielectric (ILD) layers on the first side of the interposer substrate;
forming a redistribution line in the plurality of ILD layers;
forming a top dielectric layer over the plurality of ILD layers; and
bonding a first die to the first side of the interposer substrate, wherein the first die is over the top dielectric layer, and wherein at least one of the ILD layers and the top dielectric layer has a k value lower than about 3.8.

17. The method of claim 16, further comprising bonding a second die to the second side of the interposer substrate.

18. The method of claim 16 further comprising bonding a package substrate to the second side of the interposer substrate.

19. The method of claim 16, wherein the first die comprises a dielectric layer with a k value lower than about 3.8.

20. The method of claim 16 further comprising forming a metal bump between the first die and the interposer substrate.
